(19) United States
(12) Patent Application Publication
(10) Pub. No.: US 2016/0291641 A1
(43) Pub. Date: Oct. 6, 2016

(54) METHOD AND APPARATUS FOR FLEXIBLE ELECTRONIC COMMUNICATING DEVICE

(71) Applicant: INTEL CORPORATION, Santa Clara, CA (US)

(72) Inventors: Brian S. DOYLE, Portland, OR (US); Han Wui THEN, Portland, OR (US); Valluri RAO, Saratoga, CA (US); Niloy MUKHERJEE, Portland, OR (US); Robert S. CHAU, Beaverton, OR (US); Ravi PILLARISETTY, Portland, OR (US)

(73) Assignee: Intel Corporation, Santa Clara, CA (US)

(21) Appl. No.: 15/037,639

(22) PCT Filed: Dec. 26, 2013
(86) PCT No.: PCT/US2013/077836

§ 371 Date: May 18, 2016

(51) Int. Cl. G06F 1/16; H04M 1/02; H05K 3/30; H05K 1/02; H05K 3/46

(52) U.S. Cl. CPC G06F 1/1652; H05K 1/0296; H05K 1/028; H05K 3/4682; H05K 3/30; H04M 1/0268

(57) ABSTRACT

A flexible electronic computing device is described. In one embodiment, a flexible display is formed on a flexible substrate. A plurality of electronic components are attached to the flexible substrate. A plurality of conductive signal lines are formed on the flexible substrate, the signal lines electrically coupling the electronic components to the flexible display.

### FIELD

The present application relates to display devices and, in particular, to a flexible display with included device electronics.

### BACKGROUND

Recently, a variety of different display technologies have been demonstrated on a flexible substrate. Such technologies include OLED (Organic Light Emitting Diode), e-paper and other display technologies. Polymer films and flexible glass materials provide substrates for these displays. The resulting flexible display may then be used in many new applications which are still being developed. A flexible display may be installed into a rigid frame. The rigid frame holds the display in a curved or bent shape to be wrapped around a device or structure. The curved display can also be shaped by the rigid frame to provide optimal viewing angles at one or many different positions. A flexible display can also be held in a flexible frame or no frame to allow it be curved in place to adapt to different applications.

In some concepts, a display can be rolled up into a housing in a manner similar to a projection screen. This permits a device to be used in a compact form until the display is desired. For larger displays, the display could be stored out of the way in a ceiling, wall, or cabinet until the display is needed. In other concepts, a device is wearable and bends to adapt to fit different wearers. In another concept a cellular telephone is bendable.

### BRIEF DESCRIPTION OF THE DRAWINGS

Embodiments of the invention are illustrated by way of example, and not by way of limitation, in the FIGS. of the accompanying drawings in which like reference numerals refer to similar elements.

FIG. 1 is a simplified block diagram of portable communications and computing device according to an embodiment of the invention.

FIG. 2A is a diagram of rigid technologies mounted to a rigid substrate that may be used in a flexible device according to an embodiment of the invention,

FIG. 2B is a diagram of bendable technologies mounted to or formed on a bendable substrate that may be used in a flexible device according to an embodiment of the invention.

FIG. 2C is a diagram of flexible technologies mounted to a flexible substrate that may be used in a flexible device according to an embodiment of the invention.

FIG. 2D is a diagram of flexible technologies formed on a flexible substrate that may be used in a flexible device according to an embodiment of the invention.

FIG. 3 is a diagram of a flexible display device connected to rigid components according to an embodiment of the invention.

FIG. 4 is a further diagram of a flexible display device connected to rigid components according to an embodiment of the invention.

FIG. 5 is a diagram of a flexible display device connected to a second flexible substrate and to rigid components according to an embodiment of the invention.

FIG. 6A is a diagram of a flexible display device connected to components of a flexible substrate according to an embodiment of the invention.

FIG. 6B is a diagram of a first flexible substrate for a headless device connected to components of a second flexible substrate according to an embodiment of the invention.

FIG. 7A is a diagram of a flexible display device with all of the components mounted to the same flexible substrate according to an embodiment of the invention.

FIG. 7B is a diagram of a flexible substrate of a headless device with all of the components mounted to the same flexible substrate according to an embodiment of the invention.

FIGS. 8A-8D are cross-sectional side view diagrams of a process for forming a flexible device on a flexible substrate according to an embodiment of the invention.

FIGS. 9A-9D are cross-sectional side view diagrams of an alternative process for forming a flexible device on a flexible substrate according to an embodiment of the invention.

FIGS. 10A-10D are cross-sectional side view diagrams of a second alternative process for forming a flexible device on a flexible substrate according to an embodiment of the invention.

FIG. 11 is an isometric exploded diagram view of a flexible device according to an embodiment of the invention.

### DETAILED DESCRIPTION

While flexible displays have been demonstrated in a variety of different display technologies, the drivers, processors, semiconductor devices, amplifiers, radios, sensors, and other components are not flexible. This limits possible applications of the device with a flexible display. As described herein, many components may be fabricated to be flexible while other components may be attached to flexible materials. This allows an entire device and battery to be produced as a single flexible device or as multiple flexible devices.

A variety of different implementations are described to support flexible displays. Flexible displays have been demonstrated and are typically produced by forming OLEDs, e-paper, or some other type of display devices onto a flexible polymer or glass substrate. The rest of the device, such as display drivers, processors, and batteries are then provided in a separate package or housing that is not flexible. This limits the advantages of the flexible display. Some components of the smartphone can be fabricated on a flexible display substrate. Some components can be attached to a flexible display substrate so that the substrate is flexible near and around the component. Other components can be produced separate from the display substrate as a separate flexible structure. Combinations of these techniques provide that more than the display of the device to be flexible. Other combinations provide that cooling is improved or components are smaller.

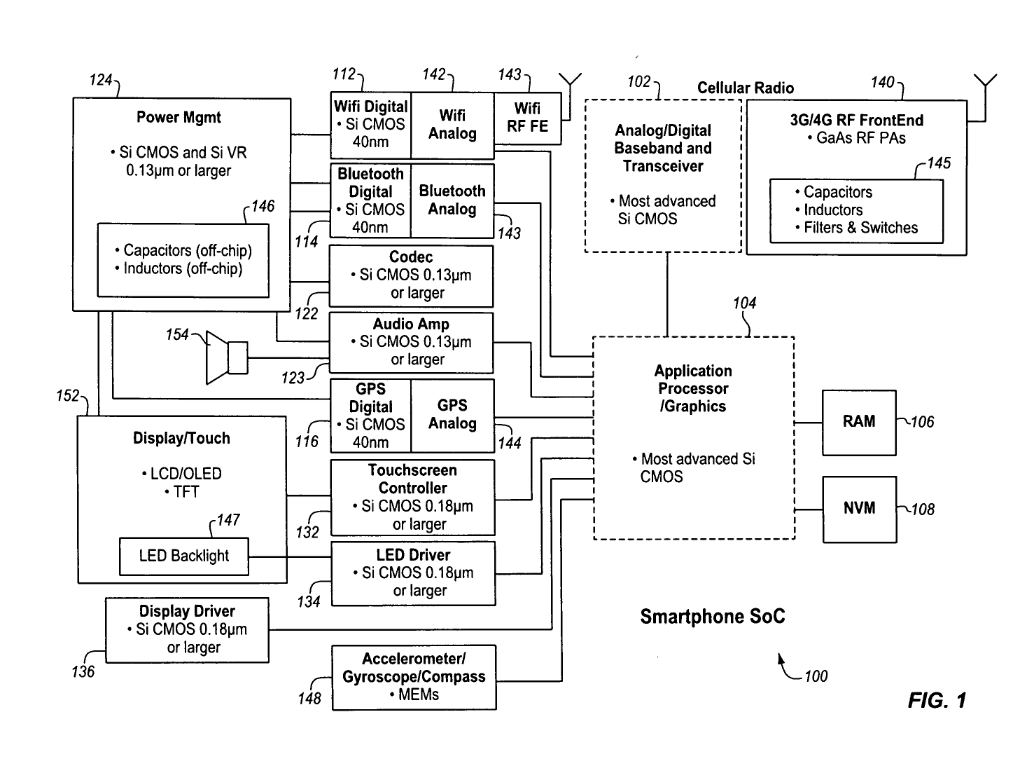

Referring to FIG. 1, an example of a smartphone or other mobile or fixed device is shown in block diagram form. The smartphone has different components which are divided up into functional blocks. It is not necessary that all of these blocks be present and there may be more or fewer blocks than those shown. In addition, some of the blocks may be combined with other blocks, depending on the particular implementation. While a smartphone is shown in this particular implementation, the same or similar blocks may be used to produce other devices, such as wearable computers, tablet computers, electronic readers, surveillance cameras or recorders, a variety of different security or environmental sensing devices, wristwatches, media players, and other devices. The same or similar approaches to those described herein may be applied to any or all such devices and more.

The smartphone 100 includes components that can easily be fabricated on a flexible substrate and those that can easily be attached to a flexible substrate. There are a number of different kinds of circuits which are fabricated using different kinds of technology. In the overall system 100 the most advanced silicon CMOS (Complementary Metal Oxide Semiconductor) technologies are used for the analog and digital base band and transceiver modules 102 that connect with the cellular radio and for the central processing unit and graphics processing unit 104.

The processors may be independent chips that are packaged together or separately or all of these functions may be combined as multiple cores on a single chip. For some devices there is no graphics processor and an application or central processor handles all of the processing functions. The processor is typically connected to a RAM (Random Access Memory) 106 and an NVM (Non Volatile Memory) 108. These are often fabricated on the same die or on a different die and packaged together with a processor. The random access and non volatile memories are often made using a highly advanced silicon CMOS process which may be as advanced or almost as advanced as that of the processor and of the base band and cellular transceiver.

Some of the components are also made in silicon CMOS but are often made using a less advanced, i.e. a less fine, manufacturing technology. As compared to a 22 nm or 12 nm manufacturing node being used for the processors and baseband dies, a coarser or larger featured technology may be used for some of the other components such as, for example, a 40 nm technology. With further advancements in silicon processing technology, more advanced nodes may be used than those provided here. These technology nodes are mentioned only to provide only a point of reference for the differences between the various components of the system 100.

The system 100 includes, for example, a Wi-Fi digital die 112, a Bluetooth digital processing die 114, a GPS (Global Positioning System) digital die 116, and other possible components that are made using a less dense or lower technology fabrication technique, such as 40 nm. An even lower resolution fabrication technique for example a 0.13 μm (130 nm) technology may be used for an audio codec 122, an audio amplifier 123, and power management circuitry 124. A still larger manufacturing technology such as 0.18 μm (180 nm) may be used for a touch screen controller 132, an LED Driver 134, and the display driver 136.

Some of the components may be made with a completely different technology. For example the cellular radio front end 140 may be made from a gallium arsenide (GaAs) RF (Radio Frequency) circuitry die. Similarly the Wi-Fi radio frequency front end 143 may also be made from gallium arsenide components. The analog portion of the Wi Fi radio 142 may also be made from larger components including gallium arsenide components. GaAs processing technology provides an inherently flexible circuit.

The system 100 may also have discrete components using other different technologies such as discrete capacitors and conductors 146 for the power management system, discrete capacitors, inductors, filters, and switches 145 for the cellular radio, backlight LEDs (Light Emitting Diodes) 147 for the display, and inertial systems 148 such as accelerometers, gyroscopes, compasses, and other components. These may be formed from a micro-electromechanical technology in a variety of different materials.

As shown in FIG. 1, all of the components mentioned above may be coupled directly or indirectly to the application and graphics processor 104. The display components 152, which may be liquid crystal (LCD) organic light omitting diode (OLED) thin filmed transistor (TFT) or any other display technology 152, may be connected to a touch screen controller 132 controlled by the graphics portion of the application processor 104. The power management system 124 is also coupled to many of the components of the system 100 any of which may require power. The power management system may be coupled to a mains supply or to a battery (not shown). The system 100 may also include speakers and microphones 154 which may be coupled to the audio amplifier 123 or to any of the variety of other devices. The speaker and microphones 154 may be built into the system or connected through a port or jack in the system so that they are removable and interchangeable.

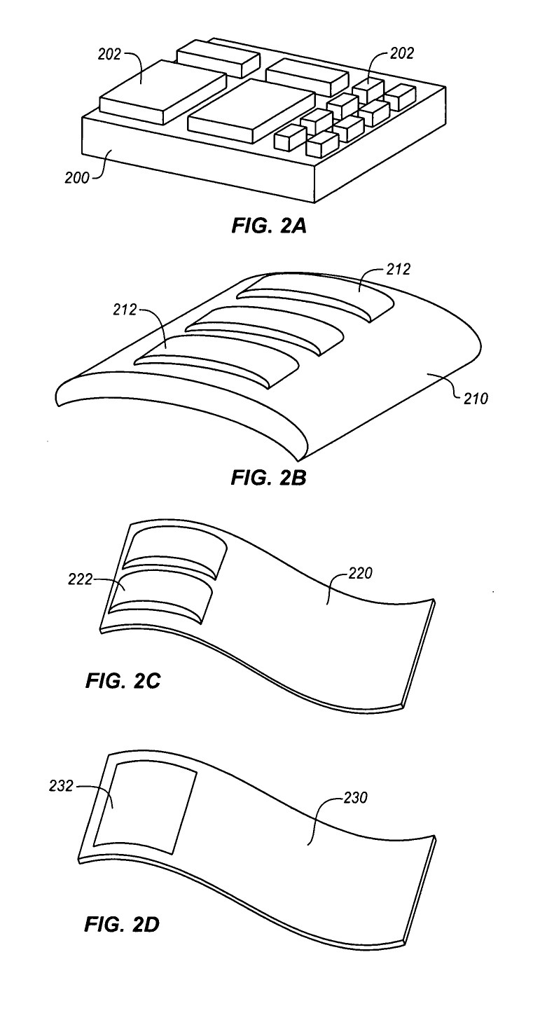

FIGS. 2A-2D are diagrams showing a variety of different technologies that may be used to produce a system or parts of a system 100 as shown above. FIG. 2A shows a rigid device manufacturing technology using a motherboard 200, logic board, system board, or a similar substrate typically of FR4 or another impregnated fiberboard technology. Such a motherboard is typically very stiff and rigid and does not sustain a significant amount of bending or flex. A number of dies 202 are attached to the motherboard typically using solder bumps or balls which do not maintain electrical and physical contact with the motherboard if the motherboard is flexed beyond some limit.

FIG. 2B shows a fabrication technology which is able to sustain some minor amount of bending. In this case a bendable substrate 210 such as glass thinned silicon, a plastic material, or some type of buildup layer material is patterned with conductive traces. Bendable dies 212 are attached to the substrate. Larger technology dies such as display drivers at a 0.18 μm or larger technology node may be formed on flexible substrates. Gallium arsenide, radio frequency circuits may also be made flexible and a limited amount of CMOS circuits on silicon substrates can also be made to be bendable to a small degree.

In one example, the dies are formed on a standard substrate using conventional silicon semiconductor manufacturing technologies. The substrate is then thinned before it is applied to the bendable substrate. This allows the die to flex with the bendable substrate. The dies may be attached in a conventional way using solder balls or bumps. The solder may be combined with polymers or other materials which allow the solder to flex with the substrate and die. Alternatively, the dies may be attached using a thermal adhesive such as thermosetting polysilicon resin that is filled with one or more conductive materials.

FIG. 2C shows a still more flexible manufacturing technology. In this case a flexible substrate such as a glass or a polymer substrate is 220 is used. Wire lines or connecting routing layers may be formed on and in the substrate using paste printing, deposition or another technique. The routing layers may then be connected to more flexible dies 222. These dies may be similar to those of FIG. 2B and may be produced in a conventional way by thinning the substrate. The dies may also be produced using bendable materials to form the die.

The dies are attached to the substrate using adhesives. These dies, stamped on the substrate, do not themselves flex to a significant degree but the spaces of substrate between the dies may flex in the same way that the substrate flexes. If the dies are small in comparison to the substrate this can provide a flexibility that is similar to that of the substrate. The substrate 220 may still be flexible without the dies being able to flex significantly.

For more flexible dies, organic or polymer electronics may be used. The circuits may be either separately or on the flexible substrate from a variety of different organic or polymer materials. These materials may include tetracene, pentacene, diindenoperylene, perylenediimides, tetracyanoquinodimethane (TCNQ), or polymers such as polythiophenes (especially poly(3-hexylthiophene) (P3HT)), polyfluorene, polydiacetylene, poly(2,5-thienylene vinylene), poly(p-phenylene vinylene) (PPV). Two-dimensional configurations may be formed using flexible connecting materials within the die and to connect the die to other components. The electrical connection may be formed from any of a variety of different materials including graphene, or metal dichalcogenides such as molybdenum disulfide, tungsten diselenide, and tungsten disulfide.

FIG. 2D shows a fourth manufacturing technology in which electronic circuitry 232 is formed directly on a flexible substrate 230. In this case the flexible substrate is also the substrate for the circuitry. This approach is used currently to produce twisted film transistors (TFT) and organic light omitting diodes on flexible substrates. The transistors are interconnected using flexible connection wiring patterns. By expanding this technology to other circuits that can be produced using similar flexible technologies, more of the system's circuitry can be produced with an ability to flex and bend with the substrate. TFT, for example can be used to produce a wide variety of different circuits of different complexity. However, TFT circuit elements are much larger than CMOS circuit elements. This makes the circuit larger and slower and requires more power. Accordingly, TFT technology works well for simpler, slower circuits, but works less well for complex microprocessors.

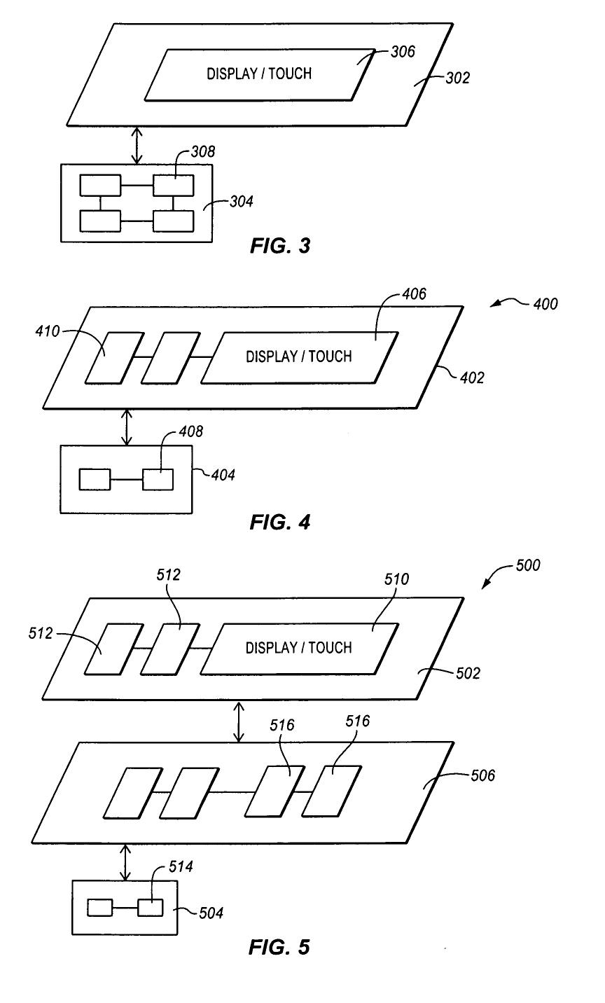

FIG. 3 is a diagram of an example flexible device 300. The device has a flexible substrate 302 upon which a display and a touch screen 306 have been fabricated. The flexible substrate is connected to a rigid motherboard 304. The display and touch screen controllers 306 are electrically connected to dies 308 mounted to the rigid motherboard 304. This example device allows the screen to be flexible. All of the rigid components are separated into a separate rigid base built around the rigid motherboard 304. The flexible display is electrically attached to the rigid base. The system 300 may also include a battery or a power supply and a housing at least for the rigid part.

FIG. 4 shows an alternative device 400 in which a portion of the circuitry and dies from the motherboard have been moved to the flexible display substrate 402. The display 406 and touch screen controllers are fabricated upon a flexible substrate 402. Additional dies 410, which may have been thinned to allow them to be bendable or which may be rigid, are fabricated on the flexible substrate 402. The dies may alternatively be formed in a separate process and then attached to the flexible substrate 402. The dies 410 may be attached using solder, using a thermoset adhesive, or using any other flexible and conductive attachment technology.

The dies 410 on the flexible substrate are connected to dies 408 on a rigid motherboard 404. In comparison to the example of FIG. 3, the example of FIG. 4 allows the rigid base to be smaller or lighter than that of FIG. 3 because some of the circuitry 308 from the rigid motherboard has been moved to the flexible substrate as shown by dies 410.

FIG. 5 is a diagram of another alternative device 500. In this case a flexible substrate 502 carries the display and touch screen controllers 510 which may be fabricated directly onto the flexible substrate. The flexible substrate may also include additional dies 512 which are either fabricated on the flexible substrate or fabricated in a separate process and stamped on to the flexible substrate. As in the example of FIG. 4, the separately formed dies may be stamped onto the flexible substrate using solder or a thermoset adhesive or any other attachment mechanism.

The circuitry of the flexible substrate is electrically connected to circuitry on a second flexible or bendable substrate 506. This circuitry 516 may be formed on the second flexible substrate 506 or it may be formed in a separate process and then attached to the second substrate 506. The second substrate 502 may be made of the same material as the first flexible substrate 502 so that they have the same bending and flexing properties. Alternatively, the second substrate may be formed of a more rigid material such as that discussed in relationship to FIG. 2B. The more rigid material may allow the device still to flex but not to the same degree as the display. While the first and second substrates are shown in the diagram as being about the same size, the second substrate may be made significantly smaller so that a portion of the device is more rigid in the area of the second substrate and more flexible away from the second substrate.

In addition to the second substrate 506, the circuitry 516 is further attached to rigid circuits 514 of a rigid motherboard 504. As in the other examples, a small part of the device may be formed on a rigid substrate. The rigid portion may be used, for example, for the most advanced silicon CMOS components such as processors and digital baseband circuitry. By forming only these components on a small rigid base, the rigid portion of the device may be made much smaller than the flexible part of the device.

The rigid high speed devices 514 are attached to the less rigid lower speed devices 516 of the bendable substrate 506 which is formed of an intermediate substrate. The intermediate substrate and devices may be made bendable at least in part. The bendable devices 516 are connected to circuitry 512 that is used to form the largest or most flexible circuits for the device. The circuitry 512 on the display substrate 502 is optional and may instead be fabricated or stamped on the intermediate substrate. The nature of this circuitry, if any, will depend on the particular implementation.

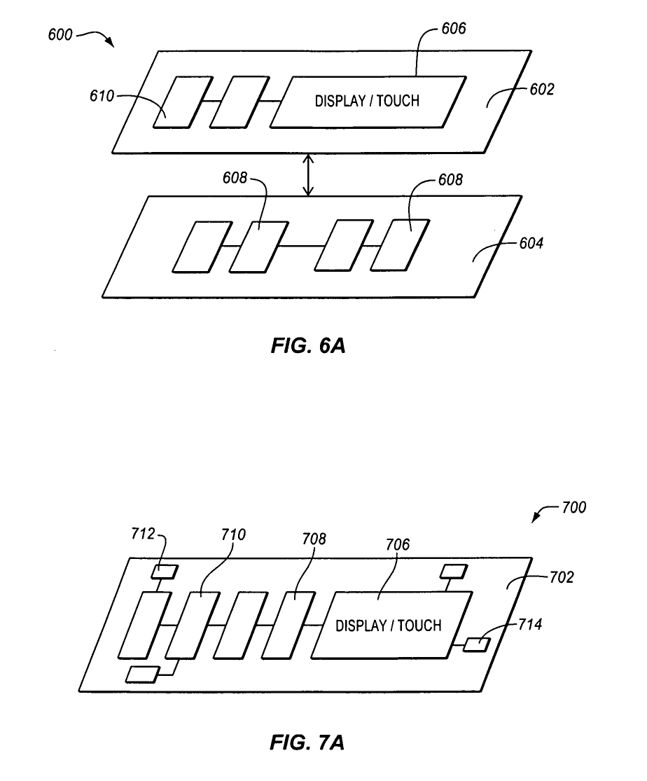

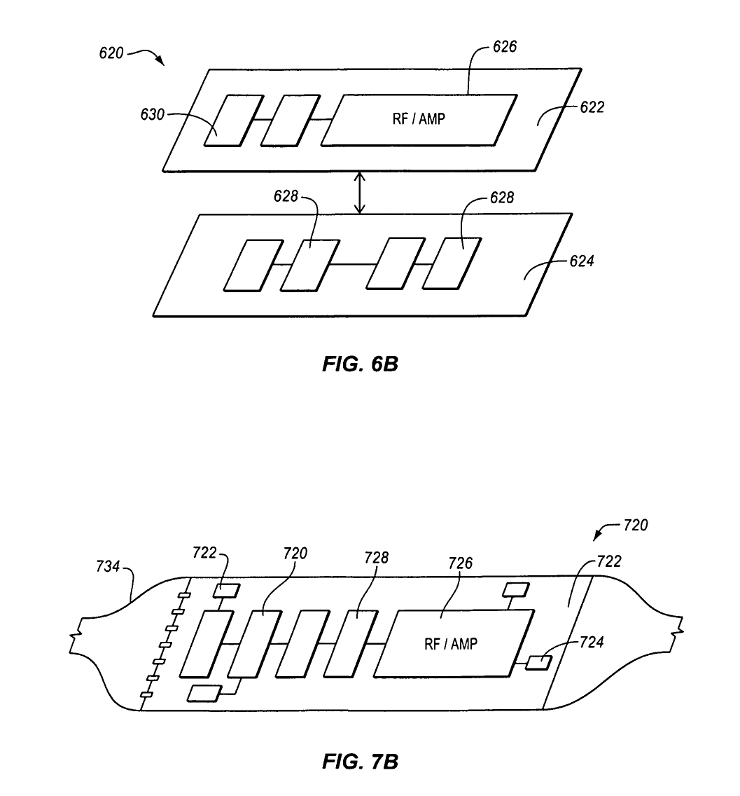

FIG. 6 shows another alternative device 600 in which all of the circuitry is formed on flexible substrates. A first substrate 602 carries the display and touch screen controller circuitry 606. This is coupled to additional circuitry 610 which may for example include power management, audio amplifiers and other analog circuitry that may be fabricated using larger components. A second substrate 604 carries the rest of the circuitry for the device. In this example there is no rigid motherboard. The circuitry 608 on the second substrate may be formed of thinned die chips, formed using flexible components, or a combination of both. The second substrate may be flexible to the same degree as that of the first substrate 602 or it may be less flexible. Its location may be confined to a small portion of the overall device 600. The circuitry 608 on the second substrate may be stamped or formed on the substrate or a combination of both. By using two different substrates, different demands of the different circuit devices may be accommodated.

FIG. 7A shows yet another alternative device 700 in which a single flexible substrate 702 is used for all the components of the device. This may be used when flexibility is very important or when the device is simpler and does not require the most advanced semiconductor circuitry technology. In the illustrated example, the display and touch screen devices 706 are formed on the flexible substrate this is coupled to flexible dies 708 which are coupled to more rigid dies 710 which may be stamped on the substrate. These are then also coupled to specific individual components 712 and 714 which are discrete rigid components or smaller dies that are limited to a very small location on the substrate 702.

The configurations of FIGS. 6A and 7A as well as those of FIGS. 3, 4, and 5, may be used for any of a variety of different devices for which processing and a display is desired, such as a media player, a smartphone, a tablet, or a camera, among others. Other devices with touch screen controller may also be provided with such an architecture such as a thermostat, a device remote control, a WiFi hotspot or other portable or small form factor data router or network bridge. By adding a strap, a smart watch, health monitor, fitness tracker, or inventory tracking device may be offered.

For some devices, a display is not necessary or desired. Devices may still be formed on or attached to a flexible substrate, however, to allow the device to be flexible. The flexibility may add comfort, convenience, or resilience against cracking. The device may be pre-programmed for operation without the need for a display, for example a sensor that sends data to a collector or that acts directly on another device such a sensor-controller system. Alternatively, the device may have an interface such as USB or Bluetooth for an external user interface. A variety of different computing, medical, and fitness devices operate in such a way. The device may have a simplified interface with a few buttons and status and alert lights, such as is used in media players, Bluetooth accessories, WiFi routers, and other devices. As a further alternative, the device may be accessible through a radio system from an external device through a browser or specialized interface program, as are many network devices and sensor systems. These different user interface and interaction examples are currently in use for many different devices and may be adapted for many more.

In the example, of further interface FIG. 6B is a diagram of a device 620 in which all of the circuitry is formed on flexible substrates but for which there is no display. A first substrate 602 carries lower density components, such as radio circuitry, amplifiers, and power systems. As shown, there is an area 626 for RF and amplifier circuits. This is coupled to additional circuitry 630 on the same substrate which may for example include power management and other analog circuitry that may be fabricated using larger components. A second substrate 624 carries the rest of the circuitry for the device. In this example there is no rigid motherboard. The circuitry 628 on the second substrate may be formed of thinned die chips, formed using flexible components, or a combination of both. The second substrate may be flexible to the same degree as that of the first substrate 622 or it may be less flexible. Its location may be confined to a small portion of the overall device 620. The circuitry 628 on the second substrate may be stamped or formed on the substrate or a combination of both. The second substrate carries the more complex circuitry, such as computing resources, digital signal processing, and memory. Either one or both of the substrates may carry a few buttons and status lights. If the status and alert indicators are made from a flexible material such as electroluminescent or OLED material, then they may be applied to either or both substrates. Similarly, touch sensitive areas may be used instead of physical switches to provide flexible buttons on either or both flexible substrate.

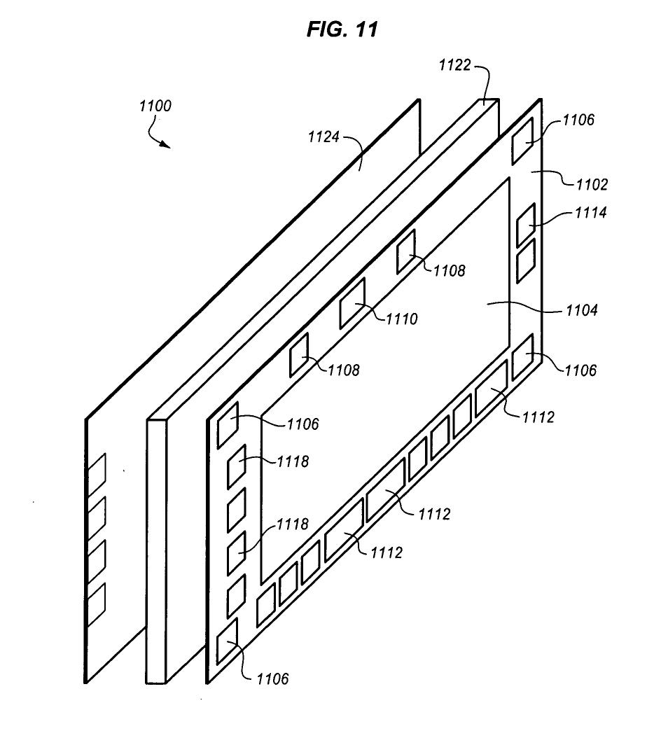

FIG. 7B shows yet another alternative device 720 with a single flexible substrate 722 for all the components of the device. In contrast to the device of FIG. 7A, this device has an external display or is headless. Such a device may be used when no display is needed or when visual, aural or other feedback and communication is sufficient for the purpose of the device. Such a device provides greater flexibility than one with two substrates. In this and any of the other examples a backer such as the core 1122 of FIG. 11 may be used to ensure that the device has sufficient resistance to bending, thickness, strength or any other desired properties. In the illustrated example, the RF and power circuits 726 are formed on the flexible substrate in one area. Other flexible dies 728 are coupled to more rigid dies 730 which may be stamped on the substrate. These are then also coupled to other specific individual components 722 and 724. These may be discrete rigid components, such as buttons, lamps, or sensors, or smaller dies that are limited to a very small location on the substrate 722. The device is also optionally fitted with a strap 734. The strap may be attached to equipment such as a pipe, tank, stand, frame, or device housing for some uses. For other uses, the strap may be attached, for example, to a person's wrist, leg, head, or chest. A flexible strap together with the flexible device may provide a higher level of versatility or comfort than has previously been available.

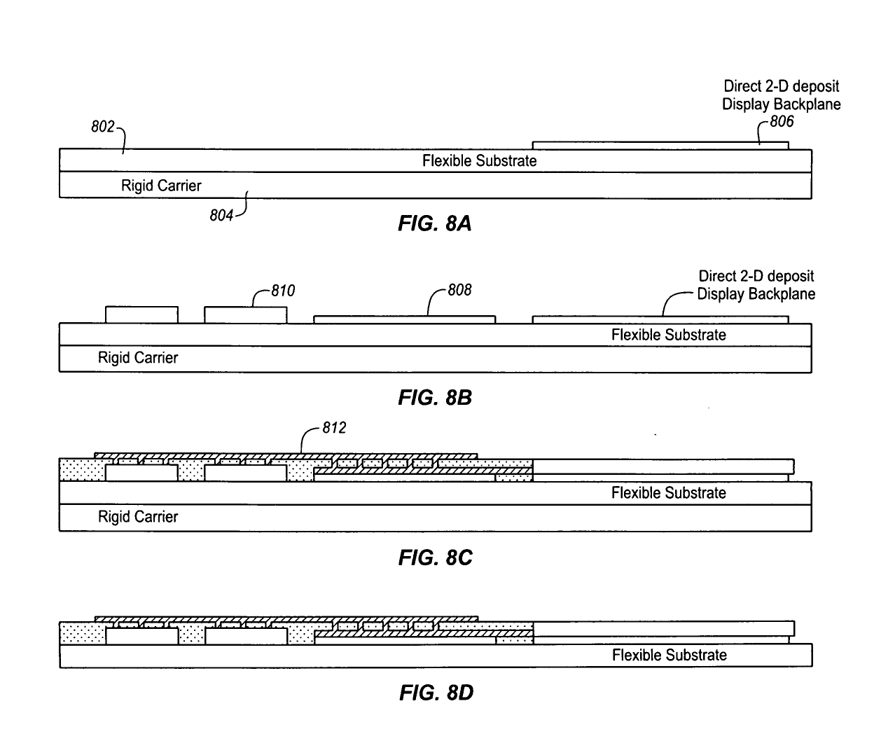

FIGS. 8A to 8D show a cross-sectional side view diagrams of examples of forming a flexible device on a flexible substrate. In FIG. 8A a flexible substrate 802 is attached to a rigid carrier 804 for handling purposes. A flexible device 806 may be formed directly on the flexible substrate. Such a device in common use today would include a display backplane and a touch screen sensor array. Other devices may also be formed directly on substrate depending on the particular implementation. In FIG. 8B this second device 808 may be formed of finer resolution components than the display using for example molybdenum disulfide carbon nanotubes or some other similar material. In addition dies 810 formed in a separate different process may also be attached to the flexible substrate. These dies may include for example a central processing unit and radio frequency circuitry.

In FIG. 8C routing layers 812 are deposited and formed over the stamped dies 810. The direct two dimensional dies 808 and the display backplane to connect all of these devices together to each other. In FIG. 8D the rigid carrier 804 is removed to provide a flexible substrate with flexible circuits formed thereon. This flexible substrate may then be packaged in a housing and connected to power supplies and other components as desired. While only three dies are shown on the substrate there may be many more. In addition, the relative positions and sizes of the display backplane and the dies may be adapted to suit different implementations.

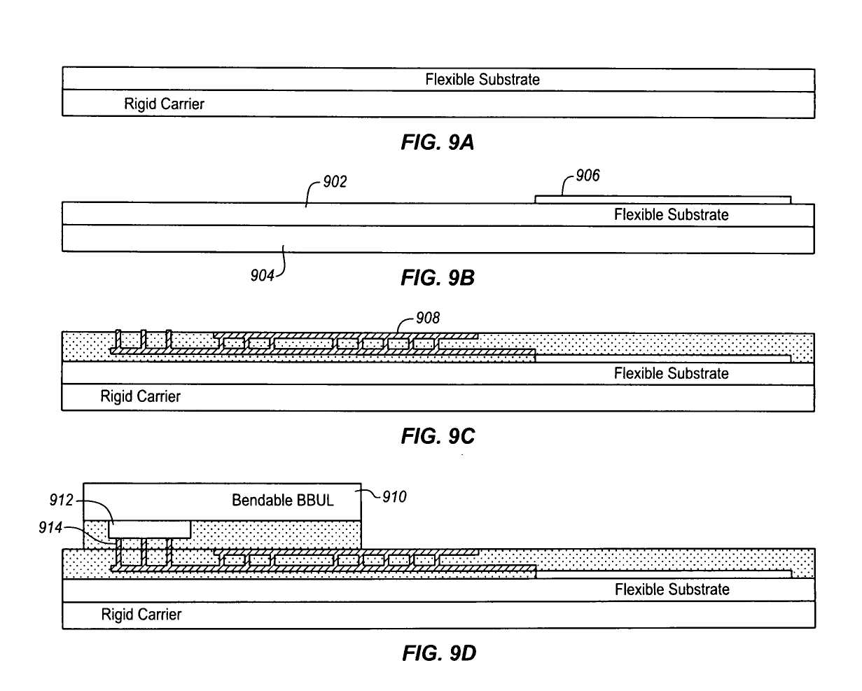

FIGS. 9A to 9D show cross-sectional side view diagrams of an alternative process for forming a flexible device as described above. In FIG. 9A a flexible substrate 902 is attached to a rigid temporary carrier 904. In FIG. 9B a display backplane and other components 906 are attached and formed over the flexible substrate. In FIG. 9C a set of routing layers 908 are deposited and formed over the flexible substrate to connect other components to the display and to each other.

In FIG. 9D a second substrate 910 and die 912 which have been formed in a separate process are attached over the routing layers 908 to form a completed flexible assembly. The substrate 910 for the stamped dies 912 may be removed or left in place to provide additional rigidity around the separate dies 912. These dies may be provided for any of the purposes of the system which require a higher speed or processing device. In the illustrated example, the die 912 is attached to a bendable buildup layer 910 as the substrate. The substrate is then covered with a silicon based dielectric layer or mold compound and vias 914 are formed through the cover. The vias make electrical connection between the die 914 and the routing layers 908. While only one die is shown, there may be many different dies of different types, depending on the particular implementation.

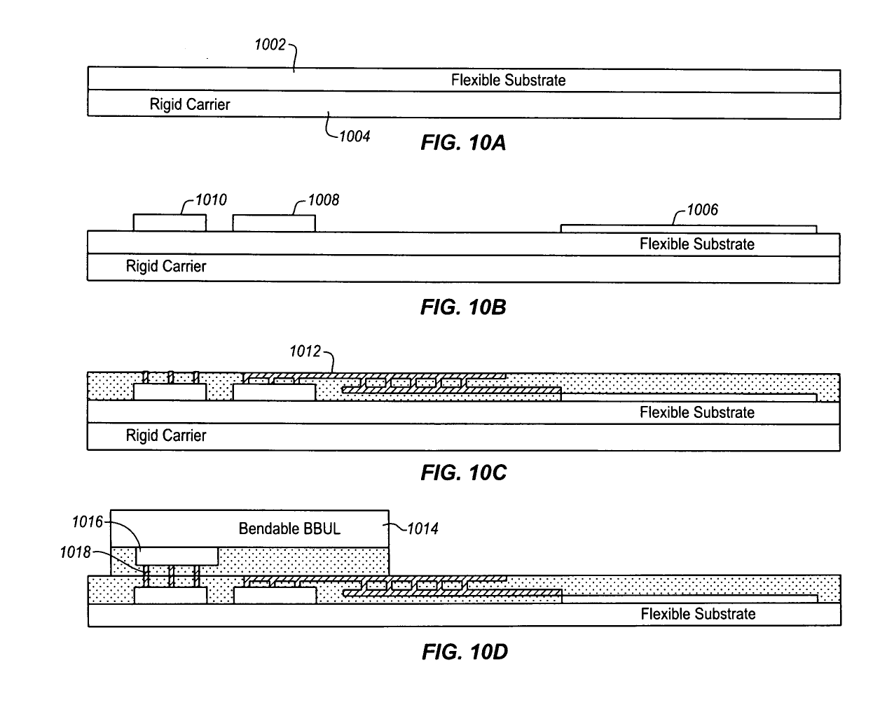

FIGS. 10A to 10D show cross-sectional diagrams of another example of forming a device using a flexible substrate. In FIG. 10A a flexible substrate 1002 is attached to a rigid carrier 1004. In FIG. 10B a display backplane 1006 is formed on the flexible substrate and dies formed in an external process are stamped onto the flexible substrate. Alternatively, one or more or all of these dies may be formed on the flexible substrate.

In FIG. 10C routing layers 1012 are formed over the stamped dies 1010, 1008 to connect the dies to the display backplane and to other components. In FIG. 10D additional dies 1016 are connected through vias 1018 to the previously stamped dies 1010, 1008. In the illustrated example the additional die 1016 is carried on a bendable substrate 1014 which provides additional connections for the additional die.

The structure of 10D, like that of 9D, provides a three dimensional stacked die configuration all formed on the flexible substrate. The rigid carrier 1004 has been removed to allow the entire device to flex with the display. In this example as in the example of FIG. 9D and 8D the left end of the device will be less flexible than the right end of the device as shown in the figures. This allows complex circuitry to be carried by the device while still allowing the device to be flexible. However the relative position and sizes of the various components may be adapted to suit different configurations.

FIG. 11 is an isometric exploded diagram view of a flexible device constructed using some of the techniques described herein. In the example of FIG. 11 the device 1100 has a flexible substrate 1102 which carries the electronics for the system and the LCD or OLED display backplane 1104. A touch screen sensor has been formed on the flexible substrate 1102. In addition several rigid components have been attached to the flexible substrate. These include microphones 1106 distributed at various positions around the device, cameras 1108 which are formed in a separate process and attached to the die, and a speaker 1110. As in other examples herein, the display is an optional feature. Other components may be formed in this area for a headless device. Alternatively, a very low resolution display and touchscreen may be used in which for example, four or five zones may be touched and information is presented to the user as one or more glowing colors in a few zones.

In addition, an array of small MEMS and other types of dies 1112 have been attached along an edge of the device. On another edge of the device RF components 1114 are attached and on another edge of the device a variety of processing circuits 1118 are attached. These may include Wi-Fi chips, Bluetooth chips, GPS chips, as well as other processors. This structure, with dies arranged around the periphery of a flexible display, allows the device to flex in the middle with a fairly rigid perimeter.

The flexible substrate 1102 may then be attached to a flexible core 1122 for the device. The core may be formed of any of a variety of flexible plastic materials. The flexible core 1122 provides some strength and rigidity to the device and controls the amount of flexibility. A large area thin film battery 1124 may be attached to the plastic core. This battery provides sufficient capacity to drive and power the device while still being flexible. The three layers may be laminated together using any of a variety of flexible adhesives and covered if desired in an outer protective flexible shell or housing (not shown).

The FIG. 11 device 110 houses a system board 1102, although there may be multiple connected system and display boards as described above. Any of the boards 1102 may include a number of components, including but not limited to the processor 1118 and communication packages 1114. The communication package is coupled to one or more antennas (not shown) on the edges of the device or between the substrates. The processor 1118 is physically and electrically coupled to the board.

Depending on its applications, communications and computing device 1100 may include other components that may or may not be physically and electrically coupled to the board 1102 as shown, for example in FIG. 1. These other components include, but are not limited to, volatile memory (e.g., DRAM), non-volatile memory (e.g., ROM), flash memory, a graphics processor, a digital signal, a crypto processor, a chipset, an antenna, a display such as a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive), optical disk, and so forth. These components may be connected to the system board 1102, mounted to the system board, or combined with any of the other components.

The communication package 1114 enables wireless and/or wired communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication package 506 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device may include a plurality of communication packages. For instance, a first communication package may be dedicated to shorter range wireless communications such as Wi-Fi and Bluetooth and a second communication package may be dedicated to longer range wireless communications such as GPS, EDGE, GPRS, CDMA, WiMAX, LTE, Ev-DO, and others.

The processor 1118 of the computing device may include an integrated circuit die packaged within the processor. The term “processor” may refer to any device or portion of a device that processes electronic data from registers and/or memory to transform that electronic data into other electronic data that may be stored in registers and/or memory.

In various implementations, the computing device may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a display device that includes a flexible display formed on a flexible substrate, a plurality of electronic components attached to the flexible substrate, and a plurality of conductive signal lines formed on the flexible substrate, the signal lines electrically coupling the electronic components to the flexible display.

In some embodiments, the plurality of electronic components is contained in at least one die package and the package is attached to the flexible substrate. In some embodiments, the die package is attached using a polymer adhesive. In some embodiments, the die package includes circuitry formed in a silicon die substrate and wherein the die substrate is thinned. In some embodiments, the conductive signal lines are formed in a polymer layer and the polymer layer is applied over the flexible substrate and over the die package.

Some embodiments include a plurality of flexible electronic components fabricated on the flexible substrate. In some embodiments, the flexible electronic components include radio frequency components formed in gallium arsenide. In some embodiments, the flexible electronic components include circuitry formed in indium gallium zinc oxide.

In some embodiments, the flexible electronic components include two-dimensional materials including at least one of graphene, or metal dichalcogenides such as molybdenum disulfide, tungsten diselenide, and tungsten disulfide.

In some embodiments, the flexible electronic components include organic or polymer electronics including at least one of tetracene, pentacene, diindenoperylene, perylenediimides, tetracyanoquinodimethane (TCNQ), or polymers such as polythiophenes (especially poly(3-hexylthiophene) (P3HT)), polyfluorene, polydiacetylene, poly(2,5-thienylene vinylene), poly(p-phenylene vinylene) (PPV)

Some embodiments pertain to a flexible computing device that includes a flexible substrate, a plurality of flexible electronic components formed on the flexible substrate, a plurality of bendable electronic components fabricated in a separate process and attached to the flexible substrate, and a routing layer formed on the flexible substrate to electrically connect components fabricated on and attached to the flexible substrate.

Some embodiments include a flexible battery to power the electronic components and a flexible core to provide structure to the device, and wherein flexible substrate, the battery and the core are physically connected with an adhesive.

Some embodiments include a third plurality of electronic components fabricated in a separate process and attached to a second flexible substrate and routing layers fabricated on the second flexible substrate to connect the third plurality of flexible components to the routing layer of the first flexible substrate.

Some embodiments pertain to a method that includes attaching a flexible substrate to a rigid substrate, forming a plurality of electronic devices on the flexible substrate, forming a routing layer on the flexible substrate to connect the electronic devices, and removing the rigid substrate.

Some embodiments include installing the flexible substrate into a housing for use. Some embodiments include attaching the flexible substrate to a second substrate before installing the first flexible substrate into the housing, the second flexible substrate having a second plurality of electronic devices.

Some embodiments include attaching a flexible battery to the second substrate and electrically connecting the battery to the second plurality of electronic devices before installing the first flexible substrate into the housing. Some embodiments include attaching a third plurality of electronic components fabricated in a separate process to the second flexible substrate. Some embodiments include attaching a third plurality of electronic components fabricated in a separate process to the first flexible substrate. Some embodiments include forming a display on a portion of the flexible substrate and connecting at least one of the plurality of electronic devices to the display.

1.-20. (canceled)

21. A display device comprising:
a flexible display formed on a flexible substrate;
a plurality of electronic components attached to the flexible substrate; and
a plurality of conductive signal lines formed on the flexible substrate, the signal lines electrically coupling the electronic components to the flexible display.

22. The device of claim 21, wherein the plurality of electronic components are contained in at least one die package and the package is attached to the flexible substrate.

23. The device of claim 22, wherein the die package is attached using a polymer adhesive.

24. The device of claim 22, wherein the die package includes circuitry formed in a silicon die substrate and wherein die substrate is thinned.

25. The device of claim 22, wherein the conductive signal lines are formed in a polymer layer and the polymer layer is applied over the flexible substrate and over the die package.

26. The device of claim 21, further comprising a plurality of flexible electronic components fabricated on the flexible substrate.

27. The device of claim 26, wherein the flexible electronic components include radio frequency components formed in gallium arsenide.

28. The device of claim 26, wherein the flexible electronic components include circuitry formed In indium gallium zinc oxide.

29. The device of claim 26, wherein the flexible electronic components include two-dimensional materials including at least one of graphene, or metal dichalcogenides such as molybdenum disulfide, tungsten diselenide, and tungsten disulfide.

30. The device of claim 26, wherein the flexible electronic components include organic or polymer electronics including at least one of tetracene, pentacene, diindenoperylene, peryleneditmides, tetracyanoquinodimethane (TCNQ), or polymers such as polythiophenes (especially poly(3-hexylthiophene) (P3HT)), polyfluorene, polydiacetylene, poly(2,5-thienylene vinylene), poly(p-phenylene vinylene) (PPV).

31. A flexible computing device comprising:
a flexible substrate;
a plurality of flexible electronic components formed on the flexible substrate;
a plurality of bendable electronic components fabricated in a separate process and attached to the flexible substrate; and
a routing layer formed on the flexible substrate to electrically connect components fabricated on and attached to the flexible substrate.

32. The device of claim 31, further comprising a flexible battery to power the electronic components and a flexible core to provide structure to the device, and wherein the flexible substrate, the battery and the core are physically connected with an adhesive.

33. The device of claim 31, further comprising:
a third plurality of electronic components fabricated in a separate process and attached to a second flexible substrate; and
routing layers fabricated on the second flexible substrate to connect the third plurality of flexible components to the routing layer of the first flexible substrate.

34. A method comprising:
attaching a flexible substrate to a rigid substrate;
forming a plurality of electronic devices on the flexible substrate;
forming a routing layer on the flexible substrate to connect the electronic devices; and
removing the rigid substrate.

35. The method of claim 34, further comprising installing the flexible substrate into a housing for use.

36. The method of claim 35, further comprising attaching the flexible substrate to a second substrate before installing the first flexible substrate into the housing, the second flexible substrate having a second plurality of electronic devices.

37. The method of claim 35, further comprising attaching a flexible battery to the second substrate and electrically connecting the battery to the second plurality of electronic devices before installing the first flexible substrate into the housing.

38. The method of claim 34, further comprising attaching a third plurality of electronic components fabricated in a separate process to the second flexible substrate.

39. The method of claim 34, further comprising attaching a third plurality of electronic components fabricated in a separate process to the first flexible substrate.

40. The method of claim 34, further comprising forming a display on a portion of the flexible substrate and connecting at least one of the plurality of electronic devices to the display.
